(19) United States
(12) Patent Application Publication
(10) Pub. No.: US 2012/0181580 A1
(43) Pub. Date: Jul. 19, 2012

(54) Semiconductor Structure and Manufacturing Method of the Same

(75) Inventors: Hang-Ting Lue, Hsinchu (TW); Shih-Hung Chen, Jhudong Township (TW)

(73) Assignee: MACRONIX INTERNATIONAL CO., LTD., Hsinchu (TW)

(21) Appl. No.: 13/008,410

(22) Filed: Jan. 18, 2011

(51) Int. Cl. H01L 27/08; H01L 21/822

(52) U.S. Cl. 257/208; 438/128; 257/E21.614; 257/E27.046

(57) ABSTRACT

A semiconductor structure and a manufacturing method of the same are provided. The semiconductor structure includes a substrate, a stacked structure, a dielectric element, a conductive line, and conductive islands. The stacked structure is formed on the substrate. The stacked structure includes conductive strips and insulating strips stacked alternately. The conductive strips are separated from each other by the insulating strips. The dielectric element is formed on the stacked structure. The conductive line is formed on the dielectric element. The conductive line is extended in a direction perpendicular to a direction which the stacked structure is extended in. The conductive islands are formed on the dielectric element. The conductive islands on the opposite sidewalls of the single stacked structure are separated from each other.

### BACKGROUND

1. Technical Field

The disclosure relates in general to a semiconductor structure and a manufacturing method of the same and more particularly to a memory device and a manufacturing method of the same.

2. Description of the Related Art

Memory devices are used in storage elements for many products such as MP3 players, digital cameras, computer files, etc. As the application increases, the demand for the memory device focuses on small size and large memory capacity. For satisfying the requirement, a memory having a high element density is need.

The critical dimension of the memory device has been decreased to the ultimate in the art. Thus, designers develop a method for improving a memory device density, using 3D stack memory device so as to increase a memory capacity and a cost per cell. However, a process for manufacturing this kind of the memory device, having a complicated structure, is complicated. In addition, an operating method is limited due to a design limitation.

### SUMMARY

The disclosure is directed to a semiconductor structure and a manufacturing method of the same.

A method for manufacturing a semiconductor structure is provided. The method comprises following steps. A stacked structure is formed on a substrate. The stacked structure comprises conductive strips and insulating strips. The conductive strips are separated from each other by the insulating strips. A dielectric element is formed on the stacked structure. Conductive lines are formed on the dielectric element. The conductive lines are extended in a direction perpendicular to a direction which the stacked structure is extended in. Conductive islands are formed on the dielectric element. The conductive islands on opposite sidewalls of the single stacked structure are separated from each other.

A semiconductor structure is provided. The semiconductor structure includes a substrate, a stacked structure, a dielectric element, a conductive line, and conductive islands. The stacked structure is formed on the substrate. The stacked structure includes conductive strips and insulating strips stacked alternately. The conductive strips are separated from each other by the insulating strips. The dielectric element is formed on the stacked structure. The conductive line is formed on the dielectric element. The conductive line is extended in a direction perpendicular to a direction which the stacked structure is extended in. The conductive islands are formed on the dielectric element.

The conductive islands on the opposite sidewalls of the single stacked structure are separated from each other.

The following description is made with reference to the accompanying drawings.

### BRIEF DESCRIPTION OF THE DRAWINGS

FIGS. 1 to 9 illustrate a process for manufacturing a semiconductor structure in one embodiment.

FIG. 10 illustrates a three dimensional view of a semiconductor structure in one embodiment.

FIG. 11 shows a three dimensional view of a semiconductor structure in one embodiment.

### DETAILED DESCRIPTION

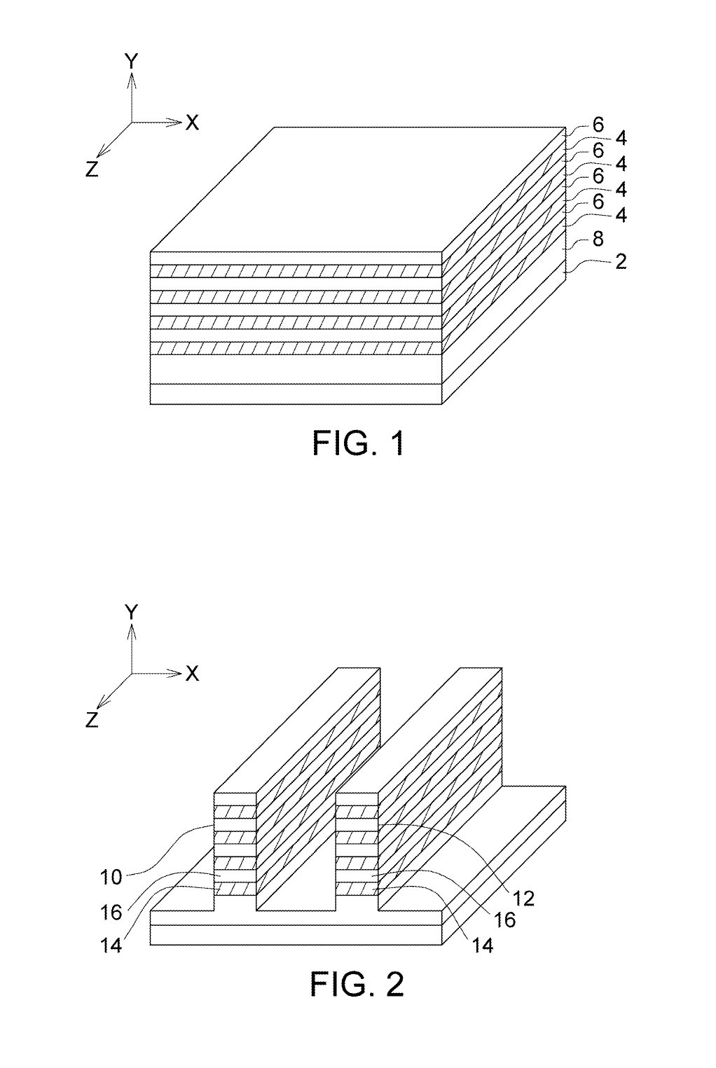

FIGS. 1 to 9 illustrate a process for manufacturing a semiconductor structure in one embodiment. Referring to FIG. 1, conductive layers 4 and insulating layers 6 are alternately stacked on a substrate 2. The conductive layers 4 are separated from each other by the insulating layers 6. The conductive layers 4 include polysilicon. In one embodiment, the conductive layers 4 may be annealed after dopping. The conductive layers 4 may also comprise a metal. The insulating layers 6 include an oxide. The substrate 2 has a buried oxide layer 8 thereon. The conductive layers 4 and the and the insulating layers 6 are patterned for forming stacked structures 10, 12 as shown in FIG. 2. The patterning method comprises a photolithography process. The stacked structures 10 and 12 each comprise alternately-stacked conductive strips 14 and insulating strips 16.

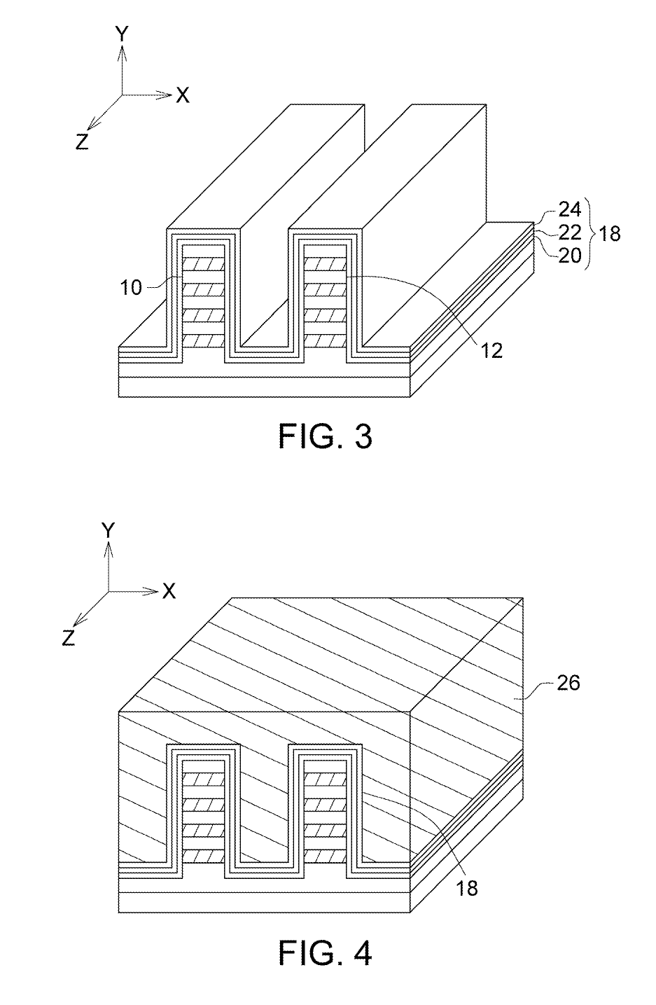

Referring to FIG. 3, a dielectric element 18 is formed on the stacked structures 10 and 12. For example, the dielectric element 18 has a multi-layers structure, for example, comprising dielectric layers 20, 22, 24. In one embodiment, the dielectric layer 20 is a silicon oxide, the dielectric layer 22 is a silicon nitride, and the dielectric layer 24 is a silicon oxide. In other embodiments, the dielectric element 18 is a single-layer dielectric material (not shown), comprising a silicon nitride, or a silicon oxide such as silicon oxide or silicon oxynitride.

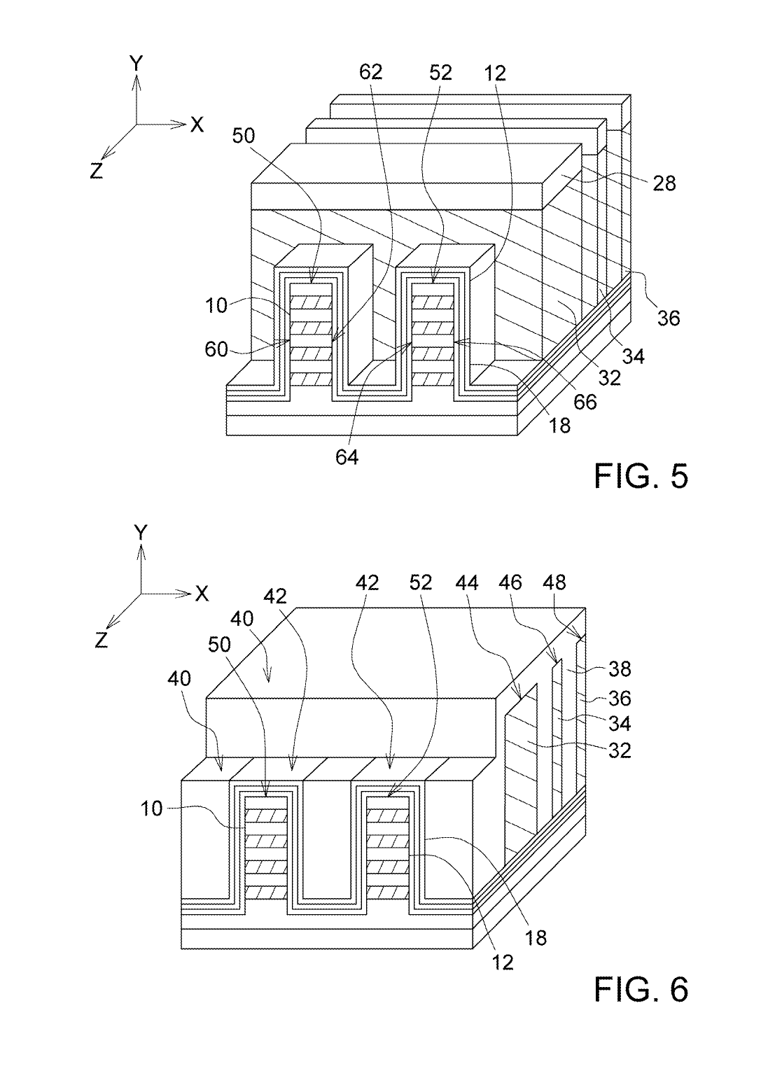

Referring to FIG. 4, a conductive layer 26 is formed on the dielectric element 18. The conductive layer 26 comprises polysilicon. The conductive layer 26 may also comprise a metal. A patterned mask layer 28 is formed on the conductive layer 26. In addition, a portion of the conductive layer 26 not covered by the patterned mask layer 28 is removed for forming conductive lines 32, 34, 36 as shown in FIG. 5. For example, the method for pattering comprises a photolithography process. In embodiments, in an etching process, the conductive layer 26 (such as a polysilicon) (FIG. 4) is etched, and the dielectric element 18 (such an ONO structure) is not etched since the process has an appropriate etching selectivity to the conductive layer 26 and the dielectric element 18.

Referring to FIG. 5, the conductive lines 32, 34, 36 are disposed on the sidewalls 60, 62, 64, 66 and the upper surfaces 50, 52 of the stacked structures 10, 12. The conductive lines 32, 34, 36 are extended in a direction (X-direction) perpendicular to a direction (Z-direction) which the stacked structures 10, 12 is extended in. The patterned mask layer 28 is removed.

Referring to FIG. 6, a dielectric layer 38 is formed on the dielectric element 18 and the conductive lines 32, 34, 36. For example, the dielectric layer 38 comprises a silicon oxide which may be formed by a deposition for a mixture vapor comprising silane and ozone, or TEOS and ozone/oxygen. The dielectric layer 38 has a flat upper surface 40. In embodiments, the upper surface 40 is aligned with or higher than the upper surface 42 of the dielectric element 18 and the upper surfaces 44, 46, 48 of the conductive lines 32, 34, 36 on the upper surfaces 50, 52 of the stacked structures 10, 12. The dielectric layer 38 having the flat upper surface 40 helps performance for a later photolithography process such as an exposing step.

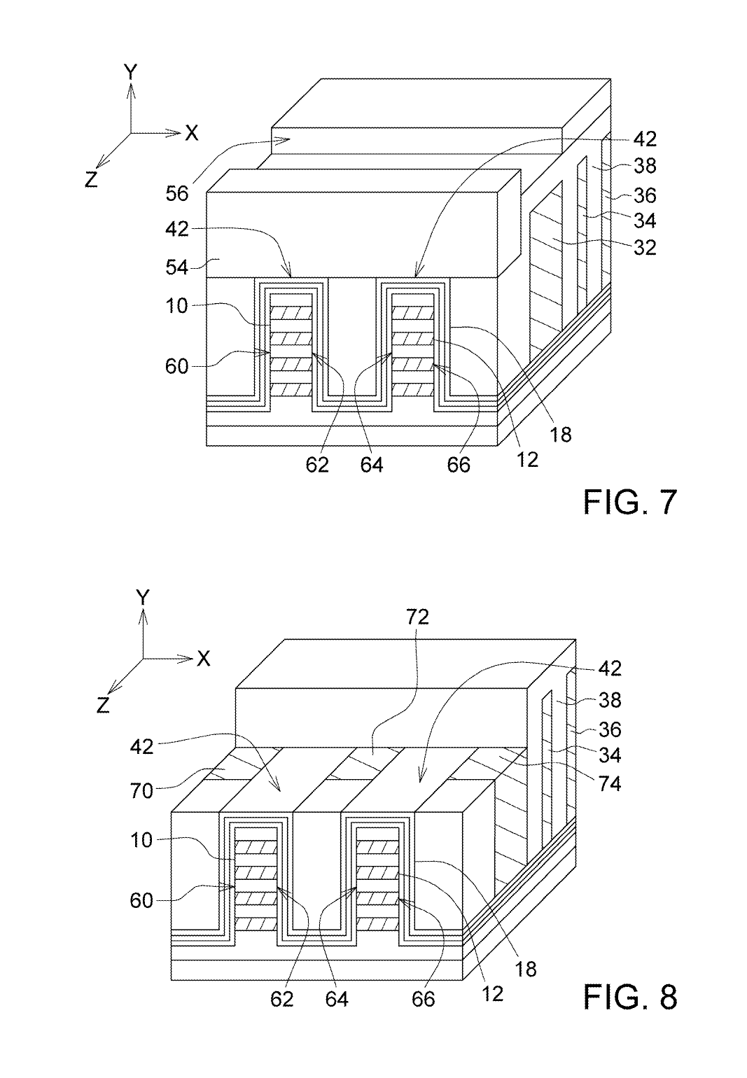

Referring to FIG. 7, a patterned mask layer 54 is formed on the dielectric layer 38. For example, the patterning method comprises a photolithography process. The patterned mask layer 54 has an opening 56 exposing the dielectric layer 38 on the conductive line 32. The dielectric layer 38 and the conductive line 32 exposed by the opening 56 is removed until the upper surface 42 of the dielectric element 18 is exposed, remaining a portion of the conductive line 32 on the opposite sidewalls 60, 62, 64, 66 of the stacked structures 10, 12 for forming conductive islands 70, 72, 74 as shown in FIG. 8. In embodiments, in an etching process, the dielectric layer 38 (such as a TEOS oxide) and the conductive line 32 (such as a polysilicon) (FIG. 7) is etched, and the dielectric element 18 (such an ONO structure) is not etched since the process has an appropriate etching selectivity to the conductive line 32, the dielectric element 18, and the dielectric layer 38. In other words, the conductive islands 70, 72, 74 are self-aligned. Therefore, the manufacturing process is simple. In other embodiments, the conductive lines 34, 36 can be properly patterned for forming other conductive islands (not shown) according to designs. The patterned mask layer 54 (FIG. 7) is removed.

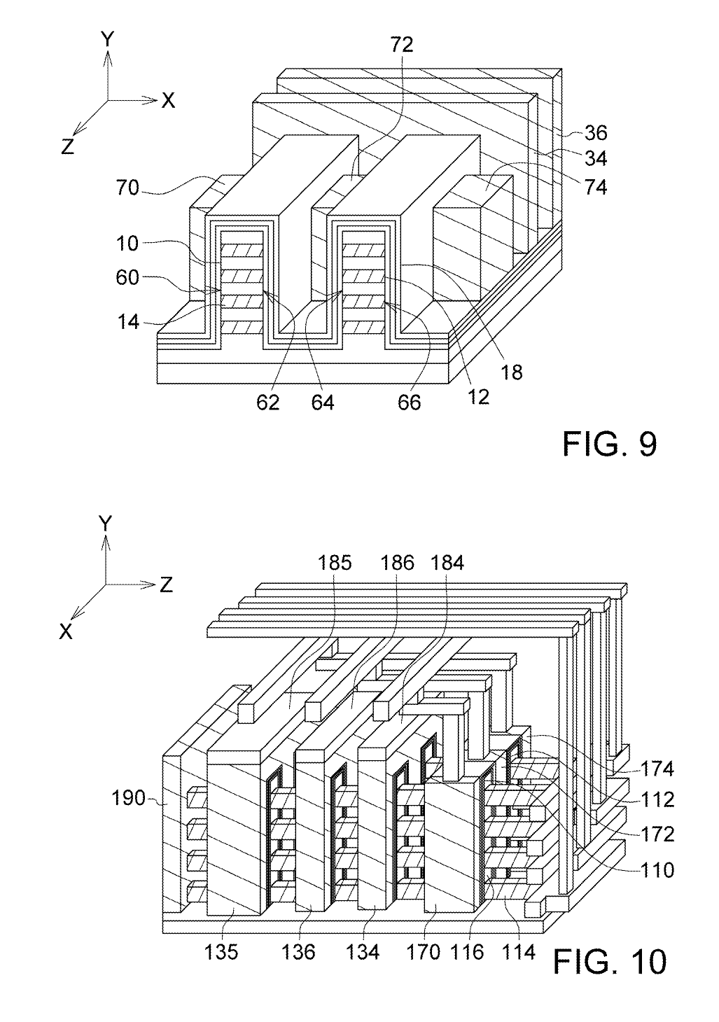

FIG. 9 does not show the dielectric layer 38 in FIG. 8. Referring to FIG. 9, the conductive islands 70 and 72 on the opposite sidewalls 60 and 62 of the stacked structure 10 are separated from each other. In addition, the conductive islands 72 and 74 on the opposite sidewalls 64 and 66 of the stacked structure 12 are separated from each other. The conductive islands 70, 72, 74 are arranged in a direction (X-direction) perpendicular to the direction (Z-direction) which the stacked structures 10, 12 are extended in.

Referring to FIG. 9, the dielectric element 18 is disposed between the stacked structures 10, 12 and the conductive lines 34, 36, and disposed between the stacked structures 10, 12 and the conductive islands 70, 72, 74. In one embodiment, the conductive lines 34, 36 and the conductive islands 70, 72, 74 have a first type conductivity. The conductive strips 14 have a second type conductivity opposite to the first type conductivity. For example, the first type conductivity is an n-type conductivity, and the second type conductivity is a p-type conductivity. The conductive islands 70, 72, 74 may be constructed of a single material or constructed of composite materials.

FIG. 10 illustrates a three dimensional view of a semiconductor structure in one embodiment. FIG. 10 does not shown a dielectric layer, as the dielectric layer 38 shown in FIG. 8, and a portion of the insulating strip 116 between the conductive islands 110, 112 and the conductive lines 134, 135, 136 (namely, the insulating strips 116 are as continuous as the conductive strips 114) of the semiconductor structure.

Referring to FIG. 10, in embodiments, the semiconductor structure is a 3D vertical gate memory device, for example, comprising a NAND flash memory and a anti-fuse memory, etc. Metal silicide layers 184, 185, 186 may be formed on the conductive lines 134, 135, 136. For example, the metal silicide layers 184, 185, 186 comprise tungsten silicide, cobalt silicide, or titanium salicide. The conductive strips 114 of different layers act as bit lines (BL) of memory cells of different planes. The conductive strips 114 are coupled with a common source line 190. The conductive lines 134, 136 act as word lines (WL). The conductive line 135 acts as a ground selection line (GSL). The conductive islands 170, 172, 174 act as string selection lines (SSL).

Referring to FIG. 10, the conductive islands 170, 172 and 174 separated from each other are applied voltages individually. Therefore, the conductive strips 114 (BL) in different stacked structures 110 and 112 are selected or unselected individually. Thus, the semiconductor structure can be used by various operating methods. In one embodiment, for example, the conductive strips 114 in the stacked structure 110 are selected by applying a positive V_{SG} (for example about +2 V to +4 V, such as about +3.3 V) to the two adjacent conductive islands 170, 172 (SSL) to turn on, and the unselected conductive strips 114 (BL) in the stacked structure 112 are turned off by applying a negative V_{inhibit} (for example about −2 V to −5 V, such as about −3.3 V) to the conductive island 174. A far SSL is turned off by applying 0 V or grounding.

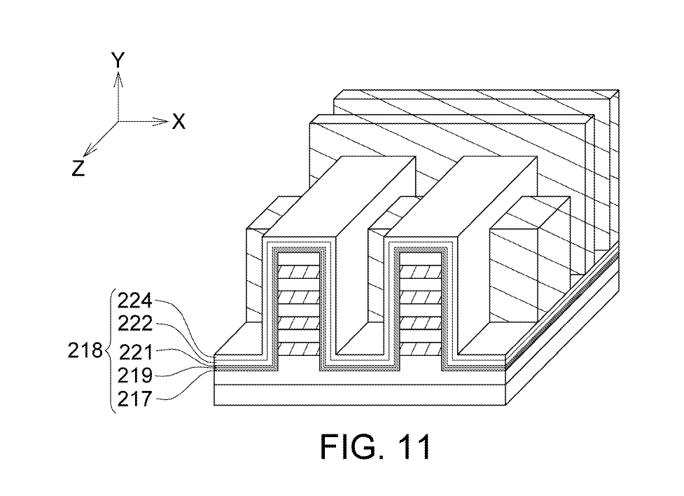

FIG. 11 shows a three dimensional view of a semiconductor structure in one embodiment. The semiconductor structure shown in FIG. 11 is different from the semiconductor structure shown in FIG. 9 in that the semiconductor structure shown in FIG. 11 has a BE-SONOS element (referring U.S. Pat. No. 7,529,137, for example). Referring to FIG. 11, the dielectric element 218 has a multi-layers structure, comprising the dielectric layers 217, 219, 221, 222, 224. In embodiments, the thicknesses of the dielectric layers 217, 219, 221 are smaller than the thicknesses of the dielectric layers 222, 224. The dielectric layers 217, 221, 224 may be silicon oxide. The dielectric layers 219, 222 may be silicon nitride.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1-8. (canceled)

9. A semiconductor structure, comprising:
a substrate;
a stacked structure formed on the substrate, wherein the stacked structure comprises conductive strips and insulating strips stacked alternately, the conductive strips are separated from each other by the insulating strips;
a dielectric element formed on the stacked structure;
a conductive line formed on the dielectric element, wherein the conductive line is extended in a direction perpendicular to a direction which the stacked structure is extended in; and
a plurality of conductive islands formed on the dielectric element, wherein the conductive islands on the opposite sidewalls of the single stacked structure are separated from each other.

10. The semiconductor structure according to claim 9, wherein the conductive islands are arranged in a direction perpendicular to the direction which the stacked structure is extended in.

11. The semiconductor structure according to claim 9, wherein the conductive island between adjacent two of the stacked structures has a single material.

12. The semiconductor structure according to claim 9, wherein the conductive island between adjacent two of the stacked structures has composite materials.

13. The semiconductor structure according to claim 9, wherein the conductive line and the conductive island have a first type conductivity, the conductive strip has a second type conductivity opposite to the first type conductivity.
